(19) United States
(12) Patent Application Publication
(10) Pub. No.: US 2022/0088880 A1
(43) Pub. Date: Mar. 24, 2022

(54) SYSTEMS AND METHODS FOR PROCESSING PARAMETER SELECTION FOR ADDITIVE MANUFACTURING USING SIMULATION

(71) Applicant: Materialise N.V., Leuven (BE)

(72) Inventor: Yogesh SOVANI, Leuven (BE)

(21) Appl. No.: 17/457,620

(22) Filed: Dec. 3, 2021

Related U.S. Application Data
(63) Continuation of application No. PCT/US2020/035992, filed on Jun. 3, 2020.
(60) Provisional application No. 62/858,907, filed on Jun. 7, 2019.

(51) Int. Cl. B29C 64/393; B29C 64/182; B33Y 50/02; G06F 30/23

(52) U.S. Cl. CPC B29C 64/393; G06F 30/23; B33Y 50/02; B29C 64/182

(57) ABSTRACT

A system and method for selecting processing parameters for build of one or more objects by additive manufacturing using simulation.

### CROSS-REFERENCE TO RELATED APPLICATIONS

This application is a continuation of International Patent Application No. PCT/US2020/035992, filed Jun. 3, 2020, which claims the benefit of U.S. Provisional Patent Application No. 62/858,907, filed Jun. 7, 2019, the entire contents of each of which are incorporated herein by reference.

### BACKGROUND

### Field of the Invention

This application relates to additive manufacturing. More particularly, this application relates to systems and methods for selecting processing parameters for build of one or more objects by additive manufacturing.

### Description of the Related Technology

In the field of additive manufacturing, three dimensional solid objects are formed from a digital model. Because the manufactured objects are three dimensional, additive manufacturing is commonly referred to as three dimensional (“3D”) printing. Some techniques for additive manufacturing include selective laser sintering (“LS”) manufacturing and metal sintering. These techniques direct a laser beam to a specified location in order to polymerize or solidify layers of building materials which are used to create the desired three dimensional (“3D”) object. The 3D object is built on a layer-by-layer basis by solidifying the layers of the building material.

An additive manufacturing apparatus (also referred to sometimes as a 3D printer) may have various parameters referred to as processing parameters that can be adjusted for manufacturing an object. The same processing parameters may be used for the entire build of the object, or different processing parameters may be used for some different portions of the object. For example, processing parameters can include one or more of a laser power (e.g., in W), a scan speed of the laser as it scans across positions of build material (e.g., in m/s), an energy density of the laser (e.g., in J/mm²), a scan time per layer meaning the time spent scanning the laser over a particular layer, a scan time for the entire build of the object, a recoater time, etc. For example, in some aspects there may be hundreds of different processing parameters for an additive manufacturing apparatus.

Selection of processing parameters for building an object is important. For example, if proper processing parameters are not selected a number of issues can arise, such as thermal issues (e.g., relating to fluid flow, thermal overheating, heat dissipation, surface color, non-uniform cooling rates, etc.), metallurgical issues (e.g., relating to microstructure, precipitation, porosity, micro-cracking, dislocation dynamics, single crystal manufacturing, etc.), mechanical issues (e.g., relating to residual stresses, distortion, stress-lines/shrinklines, location specific properties, microstructure drive property variation, etc.), etc.

Selecting processing parameters for building an object, however, may not be a simple task. For example, different sets of selected processing parameters may be needed to successfully manufacture (e.g., with a certain quality, free of defect, etc.) an object such as for different additive manufacturing apparatuses used to build an object, different object designs, and/or different materials used for building an object. If proper processing parameters are not selected for building an object, problems ranging from build crashes and damage to machinery to structural errors and distortion of parts may result.

In view of these and other problems identified by the inventors, systems and methods that improve processing parameter selection for additive manufacturing are described herein.

### SUMMARY

In one embodiment, a computer-implemented method for automatically selecting processing parameters for build of one or more objects using additive manufacturing is provided. The method includes obtaining a job file corresponding to the one or more objects. The method further includes extracting, from the job file, initial processing parameters for building the one or more objects. The method further includes performing a 2D finite difference simulation for one or more layers of the one or more objects, wherein an input to the 2D finite difference simulation comprises the extracted initial processing parameters, and wherein an output of the 2D finite difference simulation comprises temperature as a function of time at one or more locations in the one or more layers. The method further includes selecting processing parameters for building the one or more objects based on the temperature as a function of time at the one or more locations in the one or more layers, a first threshold corresponding to a lack of fusion, and a second threshold corresponding to overheating. The method further includes modifying the job file with the selected processing parameters, the job file being configured to cause an additive manufacturing device to build the one or more objects.

Certain embodiments provide a non-transitory computer-readable medium having computer-executable instructions stored thereon, which, when executed by a processor of a computing device, cause the computing device to perform the described method.

Certain embodiments provide a computing device comprising a memory and a processor configured to perform the described method.

### BRIEF DESCRIPTION OF THE DRAWINGS

FIG. 1 is an example of a system for designing and manufacturing 3D objects.

FIG. 2 illustrates a functional block diagram of one example of the computer shown in FIG. 1.

FIG. 3 shows a high level process for manufacturing a 3D object.

FIG. 4A is an example of an additive manufacturing apparatus with a recoating mechanism.

FIG. 4B is another example of an additive manufacturing apparatus with a recoating mechanism.

FIG. 5 is a flowchart of an example process for selecting processing parameters for build of an object using additive manufacturing.

FIGS. 6A and 6B are visual representations of an output of a 2D finite difference simulation for a layer of a plurality of copies of an object.

FIG. 7 is a graph of density (y-axis) versus energy (x-axis) for a layer of each of the copies of the object of FIGS. 6A and 6B based on a 2D finite difference simulation.

FIG. 8 is a flowchart of an example process for selecting processing parameters for build of an object using additive manufacturing.

### DETAILED DESCRIPTION OF CERTAIN INVENTIVE EMBODIMENTS

Systems and methods disclosed herein include techniques for selecting processing parameters for build of one or more objects by additive manufacturing using finite difference simulation. In particular, systems and methods disclosed herein provide techniques for simulation and analysis prior to build of the one or more objects that can determine a set of processing parameters suitable for building the one or more objects. In certain aspects, the set of processing parameters may be determined for a particular material. In certain aspects, the set of processing parameters may further be determined for a particular additive manufacturing apparatus. In certain aspects, the set of processing parameters may further be determined for a particular object. In certain aspects, the set of processing parameters are determined for an entire build of an object. In certain aspects, different sets of processing parameters are determined for building different portions (e.g., layers/slices) of an object.

In certain embodiments, systems and methods disclosed herein further provide automated adjustment of processing parameters for a file (e.g., job file) that is used by the additive manufacturing apparatus to build the object. Beneficially, this allows an improved resulting object as built by additive manufacturing as compared to a poor set of processing parameters. Accordingly, certain aspects provide an improvement to the field of additive manufacturing, and further provide a practical application of the described techniques in the field of additive manufacturing.

Additive manufacturing processes generally include providing energy from an energy source (e.g., a laser, an electron beam, etc.) to solidify (e.g., polymerize) layers of building material (e.g., plastic, metal, etc.). For example, the additive manufacturing machine may selectively apply energy from an energy source to (e.g., scan) the building material based on processing parameters indicated in a job file. The job file may include information regarding slices of a digital representation of an object or objects to be built using an additive manufacturing process. For example, 3D objects represented by CAD files may be arranged in a virtual build volume corresponding to the build volume of an additive manufacturing device. Optionally, support structures may be added to the 3D objects in the virtual build volume (e.g., to improve build quality, heat dissipation, reduce deformation, etc.). The resulting 3D objects may be divided into layers or slices, as discussed. The job file, accordingly, may include slices (e.g., a stack of slices) of the 3D objects, and processing parameters of the additive manufacturing machine for building the 3D objects.

For example, for each slice, the job file may include processing parameters corresponding to a scanning pattern for the energy source to apply energy to (e.g., laser to scan, electron beam to scan, etc.) the physical layer of building material corresponding to that slice. It should be noted that as discussed herein, the terms slice and layer may be used interchangeably. The scanning pattern may include one or more vectors that each indicates a spatial position to apply the energy to the layer of building material and a direction to apply the energy to the building material (e.g., a direction to move the laser beam, electron beam, or other energy source over the building material while scanning).

An additive manufacturing machine builds an object on a layer by layer basis by applying energy to (e.g., scanning) the layers of building material according to the scanning pattern for each individual layer as indicated in a job file. For example, the additive manufacturing machine may scan a first layer of physical building material corresponding to a first slice of a digital representation of an object according to the scanning pattern for the first slice. The additive manufacturing machine may then scan a second layer of building material corresponding to a second slice adjacent to the first slice according to the scanning pattern for the second slice. The additive manufacturing machine continues scanning layers of building material corresponding to all the slices in the job file, until the layer corresponding to the last slice is scanned.

Though some embodiments described herein are described with respect to certain additive manufacturing techniques using certain building materials, the described systems and methods may also be used with certain other additive manufacturing techniques and/or certain other building materials as would be understood by one of skill in the art.

In certain aspects, computing devices can be used to simulate the build of an object using additive manufacturing and processing parameters selected based on the simulation. Certain aspects provide specific simulation techniques that have low computational complexity, and therefore may reduce the number of computing cycles needed to be performed by a computing device, thereby improving functioning of the computing device to perform the simulation. In particular, certain aspects provide simulation techniques that use a 2D finite difference simulation method (using specific parameters as disclosed herein), as opposed to more computationally complex finite element method and computational fluid dynamics methods for simulating build of an object.

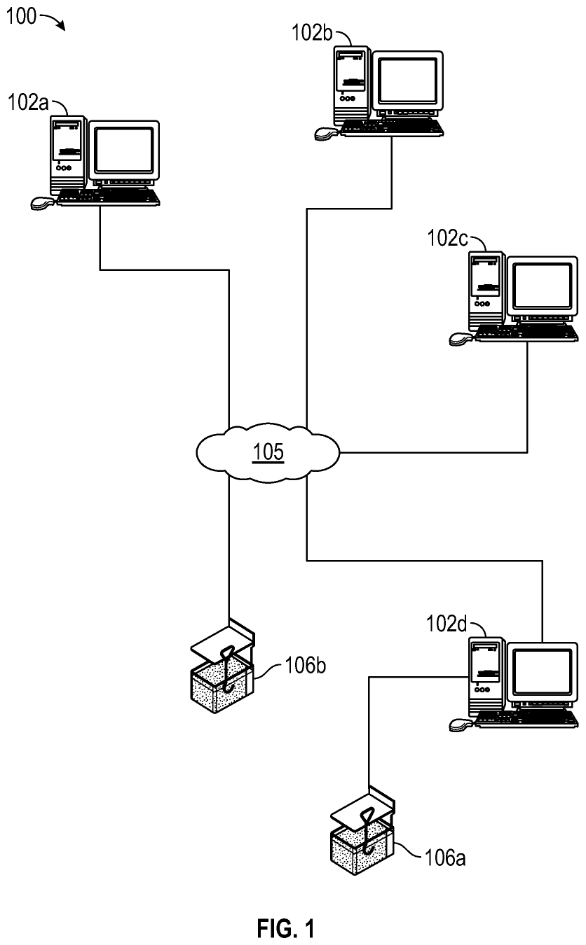

Embodiments of the invention may be practiced within a system for designing, simulating, and manufacturing 3D objects. Turning to FIG. 1, an example of a computer environment suitable for the implementation of 3D object design, build simulation, and manufacturing is shown. The environment includes a system 100. The system 100 includes one or more computers 102a-102d, which can be, for example, any workstation, server, or other computing device capable of processing information. In some embodiments, each of the computers 102a-102d can be connected, by any suitable communications technology (e.g., an internet protocol), to a network 105 (e.g., the Internet). Accordingly, the computers 102a-102d may transmit and receive information (e.g., software, digital representations of 3-D objects, commands or instructions to operate an additive manufacturing device, etc.) between each other via the network 105.

The system 100 further includes one or more additive manufacturing devices (e.g., 3-D printers) 106a-106b. As shown the additive manufacturing device 106a is directly connected to a computer 102d (and through computer 102d connected to computers 102a-102c via the network 105) and additive manufacturing device 106b is connected to the computers 102a-102d via the network 105. Accordingly, one of skill in the art will understand that an additive manufacturing device 106 may be directly connected to a computer 102, connected to a computer 102 via a network 105, and/or connected to a computer 102 via another computer 102 and the network 105.

It should be noted that though the system 100 is described with respect to a network and one or more computers, the techniques described herein also apply to a single computer 102, which may be directly connected to an additive manufacturing device 106.

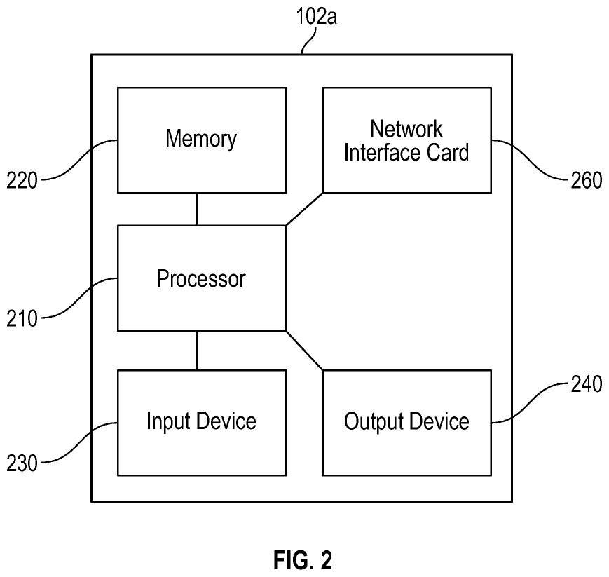

FIG. 2 illustrates a functional block diagram of one example of a computer of FIG. 1. The computer 102a includes a processor 210 in data communication with a memory 220, an input device 230, and an output device 240. In some embodiments, the processor is further in data communication with an optional network interface card 260. Although described separately, it is to be appreciated that functional blocks described with respect to the computer 102a need not be separate structural elements. For example, the processor 210 and memory 220 may be embodied in a single chip.

The processor 210 can be a general purpose processor, a digital signal processor (DSP), an application specific integrated circuit (ASIC), a field programmable gate array (FPGA) or other programmable logic device, discrete gate or transistor logic, discrete hardware components, or any suitable combination thereof designed to perform the functions described herein. A processor may also be implemented as a combination of computing devices, e.g., a combination of a DSP and a microprocessor, a plurality of microprocessors, one or more microprocessors in conjunction with a DSP core, or any other such configuration.

The processor 210 can be coupled, via one or more buses, to read information from or write information to memory 220. The processor may additionally, or in the alternative, contain memory, such as processor registers. The memory 220 can include processor cache, including a multi-level hierarchical cache in which different levels have different capacities and access speeds. The memory 220 can also include random access memory (RAM), other volatile storage devices, or non-volatile storage devices. The storage can include hard drives, flash memory, etc.

The processor 210 also may be coupled to an input device 230 and an output device 240 for, respectively, receiving input from and providing output to a user of the computer 102a. Suitable input devices include, but are not limited to, a keyboard, buttons, keys, switches, a pointing device, a mouse, a joystick, a remote control, an infrared detector, a bar code reader, a scanner, a video camera (possibly coupled with video processing software to, e.g., detect hand gestures or facial gestures), a motion detector, or a microphone (possibly coupled to audio processing software to, e.g., detect voice commands). Suitable output devices include, but are not limited to, visual output devices, including displays and printers, audio output devices, including speakers, headphones, earphones, and alarms, additive manufacturing devices, and haptic output devices.

The processor 210 further may be coupled to a network interface card 260. The network interface card 260 prepares data generated by the processor 210 for transmission via a network according to one or more data transmission protocols. The network interface card 260 also decodes data received via a network according to one or more data transmission protocols. The network interface card 260 can include a transmitter, receiver, or both. In other embodiments, the transmitter and receiver can be two separate components. The network interface card 260, can be embodied as a general purpose processor, a digital signal processor (DSP), an application specific integrated circuit (ASIC), a field programmable gate array (FPGA) or other programmable logic device, discrete gate or transistor logic, discrete hardware components, or any suitable combination thereof designed to perform the functions described herein.

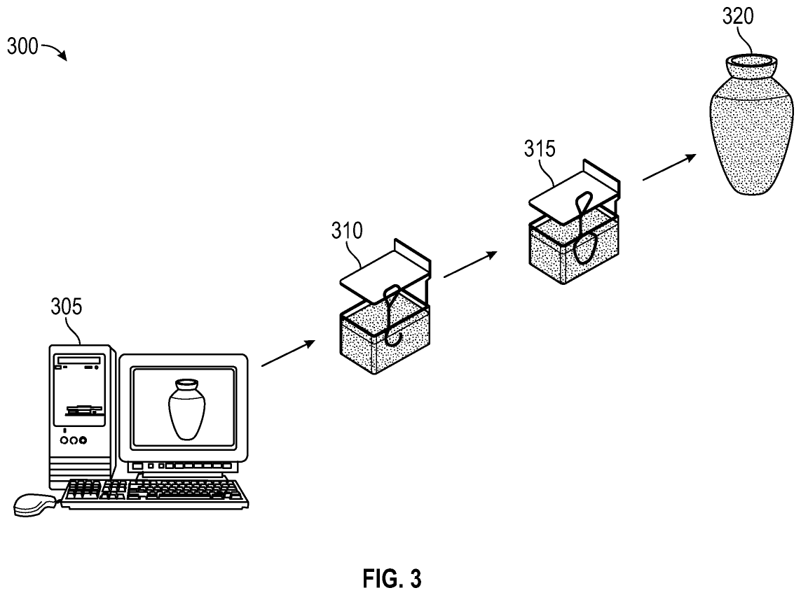

FIG. 3 illustrates a process 300 for manufacturing a 3-D object or device. As shown, at a step 305, a digital representation of the object is designed using a computer, such as the computer 102a. For example, 2-D or 3-D data may be input to the computer 102a for aiding in designing the digital representation of the 3-D object. Continuing at a step 310, information is sent from the computer 102a to an additive manufacturing device, such as additive manufacturing device 106, and the device 106 commences the manufacturing process in accordance with the received information. At a step 315, the additive manufacturing device 106 continues manufacturing the 3-D object using suitable materials, such as a polymer or metal powder. Further, at a step 320, the 3-D object is generated.

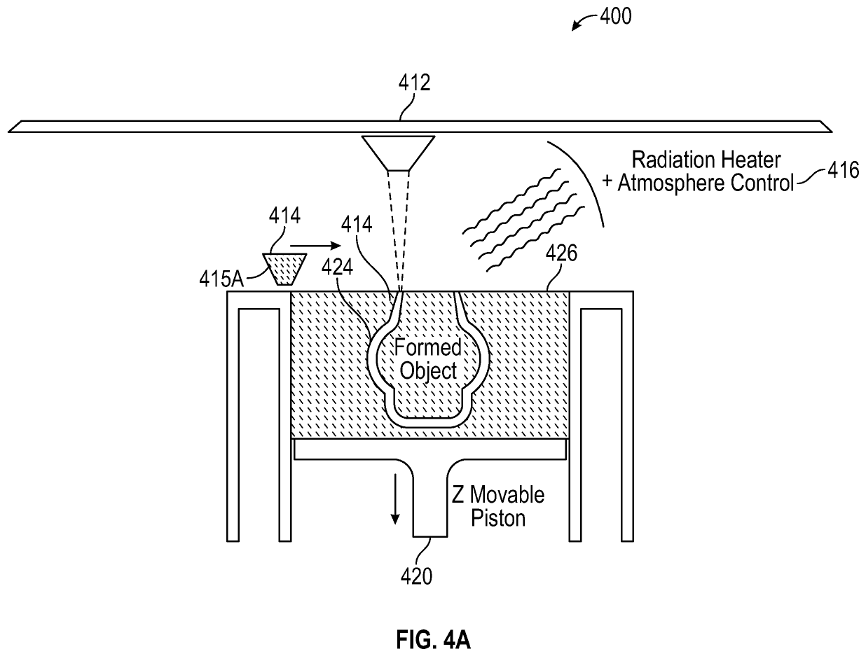

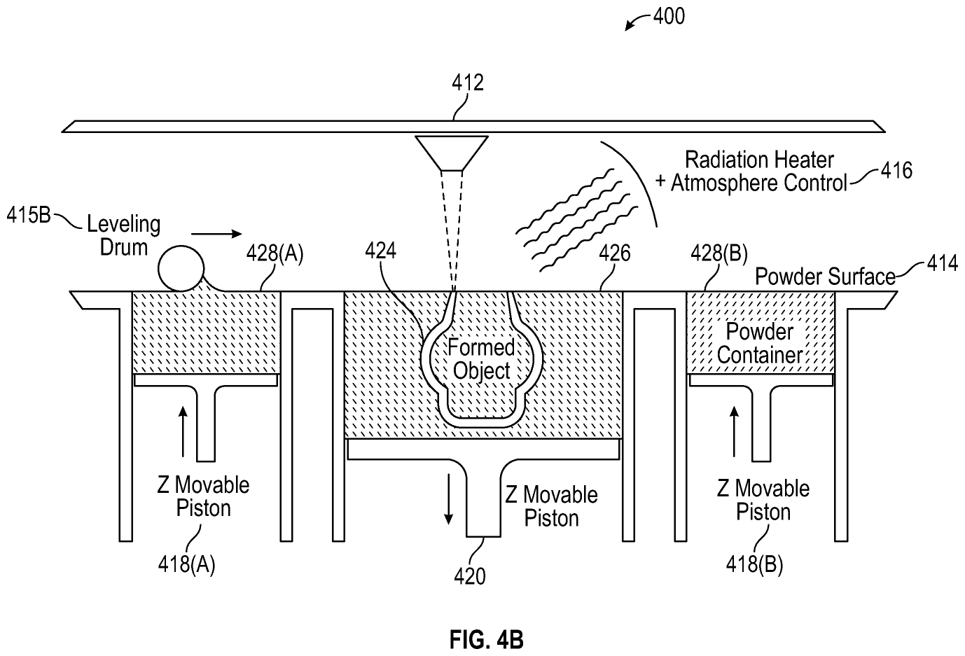

FIG. 4A illustrates an exemplary additive manufacturing apparatus 400 for generating a three-dimensional (3-D) object. In this example, the additive manufacturing apparatus 400 is a laser sintering device. The laser sintering device 400 may be used to generate one or more 3D objects layer by layer. The laser sintering device 400, for example, may utilize a powder (e.g., metal, polymer, etc.), such as the powder 414, to build an object a layer at a time as part of a build process.

Successive powder layers are spread on top of each other using, for example, a recoating mechanism 415A (e.g., a recoater blade). The recoating mechanism 415A deposits powder for a layer as it moves across the build area, for example in the direction shown, or in the opposite direction if the recoating mechanism 415A is starting from the other side of the build area, such as for another layer of the build. After deposition, a computer-controlled CO2 laser beam scans the surface and selectively binds together the powder particles of the corresponding cross section of the product. In some embodiments, the laser scanning device 412 is an X-Y moveable infrared laser source. As such, the laser source can be moved along an X axis and along a Y axis in order to direct its beam to a specific location of the top most layer of powder. Alternatively, in some embodiments, the laser scanning device 412 may comprise a laser scanner which receives a laser beam from a stationary laser source, and deflects it over moveable mirrors to direct the beam to a specified location in the working area of the device. During laser exposure, the powder temperature rises above the material (e.g., glass, polymer, metal) transition point after which adjacent particles flow together to create the 3D object. The device 400 may also optionally include a radiation heater (e.g., an infrared lamp) and/or atmosphere control device 416. The radiation heater may be used to preheat the powder between the recoating of a new powder layer and the scanning of that layer. In some embodiments, the radiation heater may be omitted. The atmosphere control device may be used throughout the process to avoid undesired scenarios such as, for example, powder oxidation.

In some other embodiments, such as shown with respect to FIG. 4B, a recoating mechanism 415B (e.g., a leveling drum/roller) may be used instead of the recoating mechanism 415A. Accordingly, the powder may be distributed using one or more moveable pistons 418(a) and 418(b) which push powder from a powder container 428(a) and 428(b) into a reservoir 426 which holds the formed object 424. The depth of the reservoir, in turn, is also controlled by a moveable piston 420, which increases the depth of the reservoir 426 via downward movement as additional powder is moved from the powder containers 428(a) and 428(b) in to the reservoir 426. The recoating mechanism 415B, pushes or rolls the powder from the powder container 428(a) and 428(b) into the reservoir 426. Similar to the embodiment shown in FIG. 4A, the embodiment in FIG. 4B may use the radiation heater alone for preheating the powder between recoating and scanning of a layer.

In certain embodiments, a suitable computing device, such as computer 102, simulates a build of an object to be built using additive manufacturing. For example, in certain embodiments, the computing device performs a 2D finite difference simulation (e.g., for each layer) of a build of an object on a layer by layer basis using a job file for the object as input (e.g., processing parameters indicated in the job file). The output of the 2D finite difference simulation is the temperature T of the object as a function f of the spatial coordinates of the location (e.g., x, y, z coordinates, where z indicates the layer depth within the build area, and x and y indicate the X-Y within the build area) and time t.

In certain aspects, the 2D finite difference simulation is based on an adaptation of a conduction equation and a heat loss equation.

In one example, the conduction equation is as follows:

$$\frac{\partial }{\partial x} ( k \frac{\partial T}{\partial x} ) + \frac{\partial }{\partial y} ( k \frac{\partial T}{\partial y} ) + \frac{\partial }{\partial z} ( k \frac{\partial T}{\partial z} ) + Q = ρ C \frac{\partial T}{\partial t}$$

where ρ, C and k refer to density, specific heat, and thermal conductivity of the build material, respectively and Q is heat flux applied (e.g., by the laser scanning device of the additive manufacturing apparatus).

In one example, the heat loss equation is as follows:

$$k ( \frac{\partial T}{\partial n} ) - {q}_{s} + {h}_{c o n v} ( T - {T}_{a m b} ) + σ ɛ ( {T}^{4} - {T}_{0}^{4} ) = 0$$

where

$$k ( \frac{\partial T}{\partial n} )$$

is heat loss due to conduction from the surface whose unit normal is n;

qₛ is heat flux as in heat input;

h_{conv}(T−T_{amb}) is heat loss due to convection;

σε(T⁴−T₀⁴) is heat loss due to radiation; and

k, h_{conv}σ, ε, T₀/T_{amb} refer to thermal conductivity, convective heat transfer co-efficient, Stefan-Boltzmann constant, emissivity, and ambient temperature, respectively.

In certain aspects, the 2D finite difference simulation is configured to adapt the conduction equation and heat loss equation to account for specific processing parameters, such as found in a job file. In certain aspects, the 2D finite difference simulation is based on a heat diffusion model. In certain aspects, the 2D finite difference simulation considers a heat source (e.g., laser) for the build as a Gaussian distribution. In certain aspects, the 2D finite difference simulation implements the effect of powder (e.g., un-melted locations) (e.g., having lower heat conductivity) as distinguished from solid material (e.g., melted zones) (e.g., as having higher heat conductivity). In certain aspects, the 2D finite difference simulation only accounts for heat transfer from the current layer being simulated (e.g., not from lower layers) so as to simplify the complexity of simulation. In certain aspects, the 2D finite difference simulation considers convection and radiation heat losses along with heat diffusion. In certain aspects, the 2D finite difference simulation extracts a toolpath from the job file. In certain aspects, the 2D finite difference simulation takes into account location based variations of processing parameters from the job file. In certain aspects, the 2D finite difference simulation implements the effect of the type of material used for building the object.

Accordingly, in certain aspects, the 2D finite difference simulation calculated temperature in 2D for each layer based in part on the following equation:

$$[ ( \frac{{T}_{i - 1 , j}^{k} - 2 {T}_{i , j}^{k} + {T}_{i + 1 , j}^{k}}{Δ {x}^{2}} ) + ( \frac{{T}_{i , j - 1}^{k} - 2 {T}_{i , j}^{k} + {T}_{i , j + 1}^{k}}{Δ {y}^{2}} ) ] = \frac{ρ {C}_{p}}{k} \times \frac{{T}_{i , j}^{k + 1} - {T}_{i , j}^{k}}{Δ t}$$

where

$$\frac{{T}_{i - 1 , j}^{k} - 2 {T}_{i , j}^{k} + {T}_{i + 1 , j}^{k}}{Δ {x}^{2}} \& \frac{{T}_{i , j - 1}^{k} - 2 {T}_{i , j}^{k} + {T}_{i , j + 1}^{k}}{Δ {y}^{2}}$$

where are Central difference representations of

$$\frac{\partial }{\partial x} ( \frac{\partial T}{\partial x} ) \& \frac{\partial }{\partial y} ( \frac{\partial T}{\partial y} )$$

in space while

$$\frac{{T}_{i , j}^{k + 1} - {T}_{i , j}^{k}}{Δ t}$$

is a Forward Euler representation of

$$\frac{\partial T}{\partial t}$$

in time. Indices i, j represent the spatial position of a point on a computation grid while index k indicates the time step.

In certain aspects, based on the output temperature T of the 2D finite difference simulation, computer 102 is configured to adjust processing parameters in the job file as further discussed herein.

Certain aspects herein provide techniques for simulating build of an object represented by a job file using 2D finite difference simulation a number of times, each time with a different set of processing parameters. Accordingly, for each set of processing parameters, the 2D finite difference simulation outputs a corresponding temperature over time for spatial locations of a simulated build of an object. For each set of processing parameters, the computing device determines if any spatial locations are likely to experience overheating and if any spatial locations are likely to experience lack of fusion (e.g., lack of melting) of build material. In certain aspects, the computing device selects a set of processing parameters that does not indicate any spatial locations that experience overheating and also does not indicate any spatial locations that experience lack of fusion. The computing device may modify the job file to use such processing parameters, and manufacture the object based on the job file.

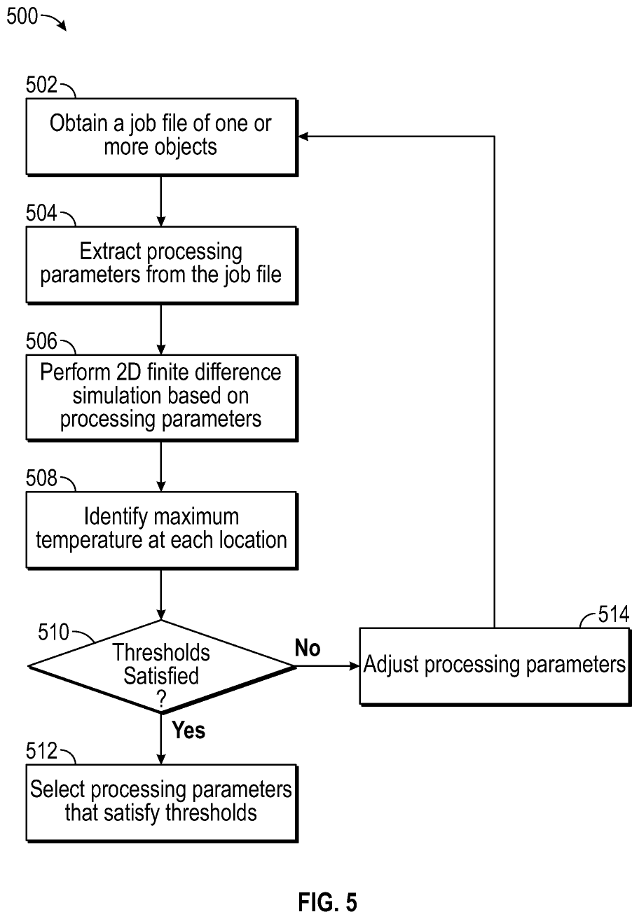

FIG. 5 is a flowchart of an example process 500 for selecting processing parameters for build of an object using additive manufacturing. The process 500 may be performed by a suitable computing device, such as a computer 102.

At block 502, the computing device obtains a job file corresponding to one or more objects. In certain aspects, the job file includes a plurality of copies of the same object, e.g., referred to as samples, and indicates a different set of processing parameters for each of the copies of the object. In certain aspects, the job file includes one or more different objects, without copies. At block 504, the computing device extracts from the job file processing parameters for building the one or more objects. For example, the computing device extracts scan vectors for each layer of the one or more objects, which define the path over which to scan build material to build the object, as well as a power, speed, etc. to use for a heat source (e.g., laser) to scan the build material. In certain aspects, the same set of processing parameters is used for the entire build of the object. In certain aspects, the set of processing parameters can vary between layers. In certain aspects, the set of processing parameters can vary between different locations of a layer (e.g., between different samples).

At block 506, the computing device performs a 2D finite difference simulation for one or more (e.g., each) layers of the one or more objects, taking as input the extracted processing parameters, and outputting temperature as a function of time at one or more locations in the one or more layers.

At block 508, the computing device identifies a maximum temperature at each of the one or more locations. The maximum temperature is the maximum temperature reached at the location over time of the simulated build (e.g., of the layer including the location). Though certain aspects are described with respect to a “maximum temperature” certain aspects instead may be based on an energy density for each location which is calculated based on the temperature as a function of time at one or more locations in the one or more layers.

At block 510, the computing device determines if any copy or copies of the one or more objects does not have a location with a maximum temperature that is above a first threshold (e.g., overheating threshold) and a location with a maximum temperature that is below a second threshold (e.g., a lack of fusion threshold).

For example, if a location is above the first threshold, the location is determined to likely experience overheating. Such local overheating can cause several different issues in the build of the object. For example, local overheating can burn the material being used to manufacture the object. This can lead to visual defects in the resulting object, such as defects in the surface color of the object.

In another example, local overheating can affect the cooling rate at those locations. For example, in areas of overheating, the rate at which an object cools at those locations is affected. Based on the cooling rate, defects may occur in the resulting object (e.g., at or near the areas of local overheating), such as defects in the structure (e.g., microstructure) of the resulting object. This can affect structural properties of the resulting object, such as hardness, shape, etc., and also lead to micro-level or macro level cracks in the resulting object.

Further, if a location is below the second threshold, the location is determined to likely experience lack of fusion. Lack of fusion occurs where there is not enough energy to fully melt the build material at a location, meaning it may not melt and solidify or fuse to other portions of the object, thereby causing defects in the build of the object.

Accordingly, overheating and/or lack of fusion during additive manufacturing can cause a resulting object to not conform to the expected designed object.

At block 512, if any copy or copies of the one or more objects do not have a location with a maximum temperature above the first threshold and do not have a location with a maximum temperature below the second threshold, that means such a copy or copies are likely not to experience either of overheating or a lack of fusion. Accordingly, the computing device may select processing parameters associated with the copy or copies as processing parameters to use for building the object, building using the additive manufacturing device simulated, and/or building using the building material used for simulation. In certain aspects, the computing device then controls build of the object using the selected processing parameters.

Instead, at block 514, if all copies of the one or more objects have a location with a maximum temperature above the first threshold or have a location with a maximum temperature below the second threshold, that means all copies are likely to experience at least one of overheating or a lack of fusion. Accordingly, at block 514, the computing device adjusts at least one processing parameter (e.g., increasing laser power or decreasing scanning speed at locations with lack of fusion, or decreasing laser power or increasing scanning speed at locations with overheating) for the one or more objects in the job file and then returns to block 502. Accordingly, processing parameters may be iteratively adjusted and simulated until a suitable set of processing parameters is selected. The one or more objects can then be successfully built using the selected processing parameters without waste of materials for multiple attempted builds.

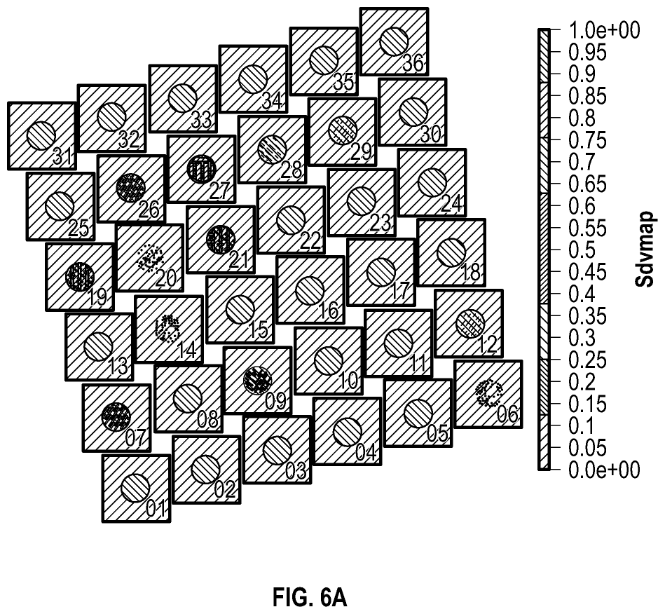

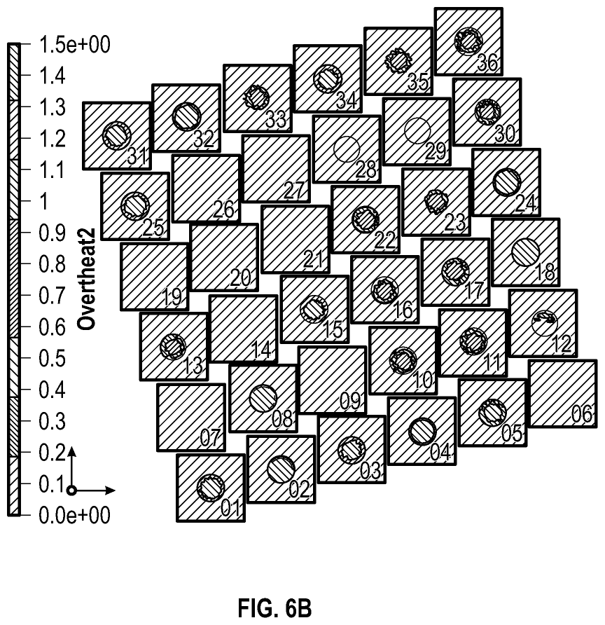

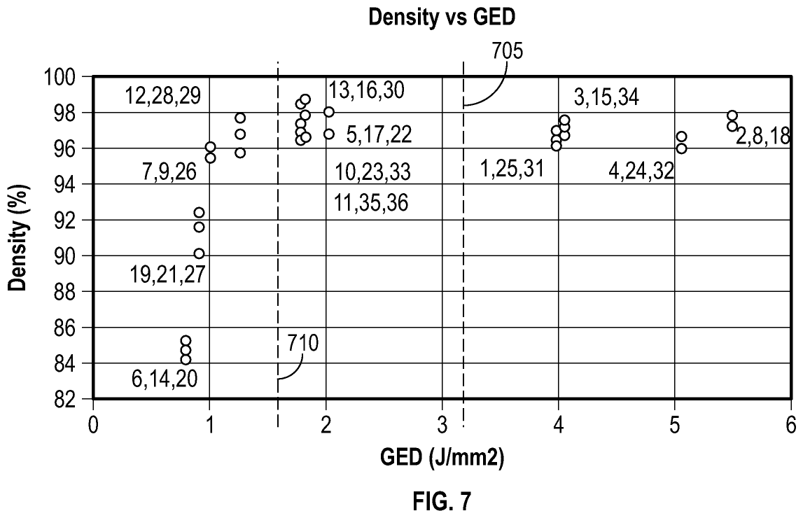

FIGS. 6A and 6B are visual representations of an output of a 2D finite difference simulation for a layer of a plurality of copies 1-36 of an object. The energy density of each copy 1-36 of the object is shown by a different color, shade, or number output (not shown) at the location on a digital representation of the object. In particular, FIG. 6A uses color and shading to represent areas with a lack of fusion. Further, FIG. 6B uses color and shading to represent areas with overheating. FIG. 7 is a graph of density (y-axis) vs energy (x-axis) for a layer of each of the copies 1-36 of the object based on the a 2D finite difference simulation. Further, the first threshold (e.g., overheating) is represented by line 705, and may be derived based on FIG. 6B, and the second threshold (e.g., lack of fusion) is represented by line 710, and may be derived based on FIG. 6A. Accordingly, copies plotted between lines 705 and 710 are considered copies having suitable processing parameters for build.

In certain aspects, processing parameters are adjusted on a layer by layer basis iteratively.

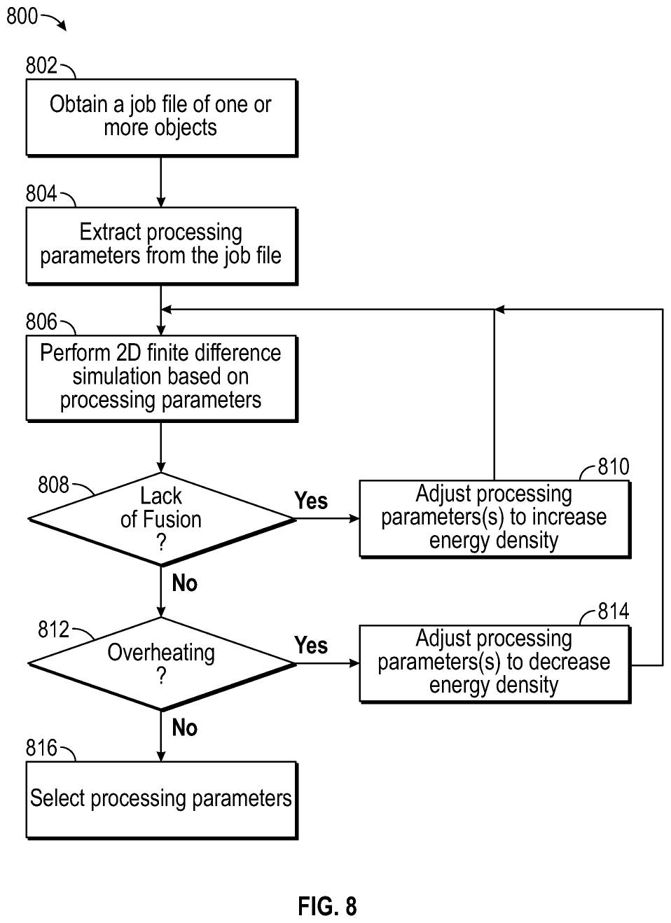

FIG. 8 is a flowchart of an example process 800 for selecting processing parameters for build of an object using additive manufacturing. The process 800 may be performed by a suitable computing device, such as a computer 102.

At block 802, the computing device obtains a job file corresponding to one or more objects. In certain aspects, block 802 is similar to block 502 of FIG. 5. At block 804, the computing device extracts from the job file processing parameters for building the one or more objects. In certain aspects, block 804 is similar to block 504 of FIG. 5.

Further, at block 806, the computing device performs a 2D finite difference simulation for a layer of the one or more objects, taking as input the extracted processing parameters, and outputting temperature as a function of time at one or more locations in the one or more layers.

At block 808, the computing device determines if any location of the object of the simulated layer has a lack of fusion. For example, the computing device determines if any location of the object has an energy density and/or maximum temperature that is below a fusion threshold.

At block 810, if there is a location of the object of the simulated layer with a lack of fusion, one or more processing parameters are adjusted to increase energy density at the location (e.g., just near the location or for the entire layer) (e.g., in the job file). For example, one or more of laser power is increased, scan speed is decreased, layer thickness is decreased, or hatch spacing is decreased. The process 800 then returns to block 806 to perform the 2D finite difference simulation for the layer with the adjusted one or more processing parameters.

At block 812, if there is no location of the object of the simulated layer with a lack of fusion, the computing device determines if any location of the object of the simulated layer has overheating. For example, the computing device determines if any location of the object has an energy density and/or maximum temperature that is above an overheating threshold.

At block 814, if there is a location of the object of the simulated layer with overheating, one or more processing parameters are adjusted to decrease energy density at the location (e.g., just near the location or for the entire layer) (e.g., in the job file). For example, one or more of laser power is decreased, scan speed is increased, layer thickness is increased, or hatch spacing is increased. The process 800 then returns to block 806 to perform the 2D finite difference simulation for the layer with the adjusted one or more processing parameters.

At block 816, if there is no location of the object of the simulated layer with overheating, the one or more processing parameters are selected as the one or more processing parameters to use for building the object, building using the additive manufacturing device simulated, and/or building using the building material used for simulation. In certain aspects, the computing device then controls build of the object using the selected processing parameters.

Various embodiments disclosed herein provide for the use of a computer control system. A skilled artisan will readily appreciate that these embodiments may be implemented using numerous different types of computing devices, including both general purpose and/or special purpose computing system environments or configurations. Examples of well-known computing systems, environments, and/or configurations that may be suitable for use in connection with the embodiments set forth above may include, but are not limited to, personal computers, server computers, hand-held or laptop devices, multiprocessor systems, microprocessor-based systems, programmable consumer electronics, network PCs, minicomputers, mainframe computers, distributed computing environments that include any of the above systems or devices, and the like. These devices may include stored instructions, which, when executed by a microprocessor in the computing device, cause the computer device to perform specified actions to carry out the instructions. As used herein, instructions refer to computer-implemented steps for processing information in the system. Instructions can be implemented in software, firmware or hardware and include any type of programmed step undertaken by components of the system.

A microprocessor may be any conventional general purpose single- or multi-chip microprocessor such as a Pentium® processor, a Pentium® Pro processor, a 8051 processor, a MIPS® processor, a Power PC® processor, or an Alpha® processor. In addition, the microprocessor may be any conventional special purpose microprocessor such as a digital signal processor or a graphics processor. The microprocessor typically has conventional address lines, conventional data lines, and one or more conventional control lines.

Aspects and embodiments of the inventions disclosed herein may be implemented as a method, apparatus or article of manufacture using standard programming or engineering techniques to produce software, firmware, hardware, or any combination thereof. The term “article of manufacture” as used herein refers to code or logic implemented in hardware or non-transitory computer readable media such as optical storage devices, and volatile or non-volatile memory devices or transitory computer readable media such as signals, carrier waves, etc. Such hardware may include, but is not limited to, field programmable gate arrays (FPGAs), application-specific integrated circuits (ASICs), complex programmable logic devices (CPLDs), programmable logic arrays (PLAs), microprocessors, or other similar processing devices.

What is claimed is:

1. A computer-implemented method for automatically selecting processing parameters for build of one or more objects using additive manufacturing, the method comprising:
obtaining a job file corresponding to the one or more objects;
extracting, from the job file, initial processing parameters for building the one or more objects;
performing a 2D finite difference simulation for one or more layers of the one or more objects, wherein an input to the 2D finite difference simulation comprises the extracted initial processing parameters, and wherein an output of the 2D finite difference simulation comprises temperature as a function of time at one or more locations in the one or more layers;
selecting processing parameters for building the one or more objects based on the temperature as a function of time at the one or more locations in the one or more layers, a first threshold corresponding to a lack of fusion, and a second threshold corresponding to overheating; and
modifying the job file with the selected processing parameters, the job file being configured to cause an additive manufacturing device to build the one or more objects.

2. The method of claim 1, wherein the 2D finite difference simulation is based on a conduction equation and a heat loss equation.

3. The method of claim 1, wherein the processing parameters comprise one or more of a laser power, a scan speed, a scan time, or a recoater time.

4. The method of claim 1, wherein:
the one or more objects comprise a plurality of copies of a same object, each copy being associated with a different set of processing parameters; and
selecting the processing parameters comprises:
determining a maximum temperature at each of the one or more locations; and
selecting the processing parameters as a set of processing parameters associated with a copy including no locations with a maximum temperature that is above the second threshold and no locations with a maximum temperature that is below the first threshold.

5. The method of claim 1, wherein selecting the processing parameters comprises:
determining, for each of the one or more locations, if a temperature at the location fails to satisfy the first threshold or the second threshold;
for any location that does not satisfy the first threshold, adjusting the initial processing parameters to increase an energy density at the location; and
for any location that does not satisfy the second threshold, adjusting the initial processing parameters to decrease an energy density at the location.

6. The method of claim 5, wherein adjusting the initial processing parameters is done on a layer by layer basis.

7. The method of claim 1, wherein:
the one or more objects comprise a plurality of copies of a same object, each copy being associated with a different set of processing parameters; and
selecting the processing parameters comprises:
determining an energy density at each of the one or more locations; and
selecting the processing parameters as a set of processing parameters associated with a copy including no locations with an energy density that is above the second threshold and no locations with an energy density that is below the first threshold.

8. The method of claim 1, wherein selecting the processing parameters comprises:
determining, for each of the one or more locations, if an energy density at the location fails to satisfy the first threshold or the second threshold;
for any location that does not satisfy the first threshold, adjusting the initial processing parameters to increase the energy density at the location; and
for any location that does not satisfy the second threshold, adjusting the initial processing parameters to decrease the energy density at the location.

9. The method of claim 8, wherein adjusting the initial processing parameters is done on a layer by layer basis.

10. The method of claim 1, further comprising causing manufacturing of the one or more objects using additive manufacturing.

11. A non-transitory computer-readable medium having computer-executable instructions stored thereon, which, when executed by a processor of a computing device, cause the computing device to perform operations comprising:
obtaining a job file corresponding to one or more objects;
extracting, from the job file, initial processing parameters for building the one or more objects;
performing a 2D finite difference simulation for one or more layers of the one or more objects, wherein an input to the 2D finite difference simulation comprises the extracted initial processing parameters, and wherein an output of the 2D finite difference simulation comprises temperature as a function of time at one or more locations in the one or more layers;
selecting processing parameters for building the one or more objects based on the temperature as a function of time at the one or more locations in the one or more layers, a first threshold corresponding to a lack of fusion, and a second threshold corresponding to overheating; and
modifying the job file with the selected processing parameters, the job file being configured to cause an additive manufacturing device to build the one or more objects.

12. A computing device comprising:
a memory; and
a processor configured to cause the computing device to perform operations comprising:
obtaining a job file corresponding to one or more objects;
extracting, from the job file, initial processing parameters for building the one or more objects;
performing a 2D finite difference simulation for one or more layers of the one or more objects, wherein an input to the 2D finite difference simulation comprises the extracted initial processing parameters, and wherein an output of the 2D finite difference simulation comprises temperature as a function of time at one or more locations in the one or more layers;
selecting processing parameters for building the one or more objects based on the temperature as a function of time at the one or more locations in the one or more layers, a first threshold corresponding to a lack of fusion, and a second threshold corresponding to overheating; and
modifying the job file with the selected processing parameters, the job file being configured to cause an additive manufacturing device to build the one or more objects.
